(19) United States
(12) Patent Application Publication
(10) Pub. No.: US 2024/0385248 A1
(43) Pub. Date: Nov. 21, 2024

(54) ENERGY STORAGE APPARATUS, METHOD FOR OBTAINING BATTERY STATE OF HEALTH VALUE, AND BATTERY MANAGEMENT SYSTEM

(71) Applicant: Huawei Digital Power Technologies Co., Ltd., Futian District (CN)

(72) Inventor: Jie XIE, Shenzhen (CN)

(73) Assignee: Huawei Digital Power Technologies Co., Ltd., Futian District (CN)

(21) Appl. No.: 18/665,878

(22) Filed: May 16, 2024

(30) Foreign Application Priority Data
May 18, 2023 (CN) 202310568161.X

(51) Int. Cl. G01R 31/367; G01R 31/385; G01R 31/392; G01R 31/396

(52) U.S. Cl. CPC G01R 31/367; G01R 31/386; G01R 31/392; G01R 31/396

(57) ABSTRACT

An energy storage apparatus includes a battery control unit, a battery monitor unit, and a plurality of cells. The battery control unit is configured to receive a battery state of health (SoH) value estimation model from cloud device, and the battery monitor unit is configured to obtain an estimated SoH value of a first cell based on a real-time equivalent circuit model parameter of the first cell in the plurality of cells and the battery SoH value estimation model. According to the energy storage apparatus, a battery SoH value is estimated by using an artificial intelligence model, and deep charging and discharging do not need to be performed on a battery, so that the battery SoH value can be accurately obtained in a plurality of application scenarios, and a battery capacity abnormality risk can be identified in advance, thereby improving stability of an energy storage system.

### CROSS-REFERENCE TO RELATED APPLICATION

This application claims priority to Chinese Patent Application No. 202310568161.X, filed on May 18, 2023, which is hereby incorporated by reference in its entirety.

### TECHNICAL FIELD

The embodiments relate to the energy field and an energy storage apparatus, a method for obtaining a battery state of health value, and a battery management system.

### BACKGROUND

With the development of energy storage technologies, a lithium-ion battery is increasingly used in various mobile or fixed devices. To ensure stable operation of the devices, a power supply battery needs to be managed, to identify potential risks of the battery in advance, and perform maintenance in advance to avoid serious consequences. A battery state of health (SoH) value is an important parameter in a battery management system. The battery state of health indicates a ratio of a real-time capacity to a rated capacity of the battery, and is generally expressed in percentage. The battery SoH value can be obtained by performing a full charge test or a full discharge test on the battery. However, due to a plurality of factors like safety, the battery cannot be fully charged and discharged. Therefore, the battery SoH value cannot be accurately measured.

Currently, a method widely used in the industry is to establish a relationship between a battery retention capacity and an online detection parameter, and estimate the battery SoH value by using a charge/discharge curve. However, the method needs to first obtain an aging model through a prior aging test that requires a heavy workload and a long period. In addition, in a plurality of power backup scenarios, for example, in scenarios such as a data center and a station backup power supply, the battery is in a float charging state for long time, and a voltage and a current almost remain unchanged. The foregoing method for estimating the battery SoH value based on the charge/discharge curve cannot be performed.

Therefore, an energy storage apparatus is urgently needed to accurately obtain the battery SoH value in the plurality of application scenarios, to identify a battery capacity abnormality risk in advance, and improve stability of an energy storage system.

### SUMMARY

The embodiments provide an energy storage apparatus, a method for obtaining a battery state of health value, and a battery management system, to help accurately obtain the battery state of health (SoH) value, identify a battery capacity abnormality risk in advance, and improve stability of the energy storage system.

According to a first aspect, an energy storage apparatus is provided, where the energy storage apparatus includes a battery control unit (BCU) and at least one battery pack, the battery pack includes a battery monitor unit (BMU) and a plurality of cells, the plurality of cells is connected in series, the battery control unit BCU is connected to the at least one battery pack, and the battery monitor unit BMU is connected to a first cell of the plurality of cells. The battery control unit BCU is configured to receive a battery state of health (SoH) value estimation model from a cloud device, where the battery SoH value estimation model is obtained by the cloud device through training based on historical equivalent circuit model parameters of the plurality of cells and historical actual SoH values of the plurality of cells, equivalent circuit model parameters of the plurality of cells include at least one of equivalent inductance parameters, equivalent capacitance parameters, and equivalent resistance parameters of the plurality of cells, and the historical equivalent circuit model parameters of the plurality of cells one-to-one correspond to the historical actual SoH values of the plurality of cells. The battery monitor unit BMU is configured to obtain a real-time equivalent circuit model parameter of the first cell, and obtain an estimated SoH value of the first cell based on the real-time equivalent circuit model parameter of the first cell and the battery SoH value estimation model.

According to the energy storage apparatus in the embodiments, a battery SoH value is estimated by using an artificial intelligence model, and deep charging and discharging do not need to be performed on the battery, so that the battery SoH value can be accurately obtained in a plurality of application scenarios, and a battery capacity abnormality risk can be identified in advance, thereby improving stability of an energy storage system.

With reference to the first aspect, in some implementations of the first aspect, the battery monitor unit BMU is further configured to: send an alternating current excitation electrical signal to the first cell, where a frequency of the alternating current excitation electrical signal is a preset value; and obtain a sampling signal from the first cell, where the sampling signal is used to obtain the real-time equivalent circuit model parameter of the first cell, and the sampling signal includes at least one of voltage information, current information, and temperature information that are of the first cell.

With reference to the first aspect, in some implementations of the first aspect, a frequency at which the battery monitor unit BMU obtains the sampling signal from the first cell is f₁, a frequency at which the battery monitor unit BMU sends the alternating current excitation electrical signal to the first cell is f₂, and f₁ and f₂ meet: f₁≥2f₂. In this way, a sampling frequency is more than twice a frequency of sending the alternating current excitation electrical signal, and accuracy of the sampling signal can be ensured.

With reference to the first aspect, in some implementations of the first aspect, the battery monitor unit BMU is configured to: parse the sampling signal and the alternating current excitation signal to obtain impedance spectrum information of the first cell; and obtain the real-time equivalent circuit model parameter of the first cell based on the impedance spectrum information of the first cell and a battery equivalent circuit model, where the battery equivalent circuit model is preconfigured or stored in the battery monitor unit BMU.

With reference to the first aspect, in some implementations of the first aspect, the battery control unit BCU is further configured to send the historical equivalent circuit model parameters of the plurality of cells and the historical actual SoH values of the plurality of cells to the cloud device.

With reference to the first aspect, in some implementations of the first aspect, the battery control unit BCU is further configured to send, to the cloud device, the real-time equivalent circuit model parameter of the first cell and an actual SoH value that is of the first cell and that corresponds to the real-time equivalent circuit model parameter of the first cell, where the real-time equivalent circuit model parameter of the first cell and the actual SoH value that is of the first cell and that corresponds to the real-time equivalent circuit model parameter of the first cell are used by the cloud device to update the battery SoH value estimation model, to obtain an updated battery SoH value estimation model. In this way, in use of the battery SoH value estimation model, continuous iteration may be performed based on an actual SoH value of a cell and an estimated SoH value of the cell, thereby improving precision of the battery SoH value estimation model.

With reference to the first aspect, in some implementations of the first aspect, the battery control unit BCU is further configured to receive the updated battery SoH value estimation model from the cloud device.

With reference to the first aspect, in some implementations of the first aspect, a waveform of the alternating current excitation electrical signal includes at least one of a sine wave, a square wave, or a triangular wave.

According to a second aspect, this application provides a method for obtaining a battery state of health (SoH) value, where the method is executed by an energy storage apparatus, the energy storage apparatus includes at least one battery pack, the battery pack includes a plurality of cells, the plurality of cells are connected in series, and the plurality of cells include a first cell. The method includes: receiving a battery SoH value estimation model from a cloud device, where the battery SoH value estimation model is obtained by the cloud device through training based on historical equivalent circuit model parameters of the plurality of cells and historical actual SoH values of the plurality of cells, equivalent circuit model parameters of the plurality of cells include at least one of equivalent inductance parameters, equivalent capacitance parameters, and equivalent resistance parameters of the plurality of cells, and the historical equivalent circuit model parameters of the plurality of cells one-to-one correspond to the historical actual SoH values of the plurality of cells; and obtaining a real-time equivalent circuit model parameter of the first cell, and obtaining an estimated SoH value of the first cell based on the real-time equivalent circuit model parameter of the first cell and the battery SoH value estimation model.

According to the method in the embodiments, a battery SoH value is estimated by using an artificial intelligence model, and deep charging and discharging do not need to be performed on the battery, so that the battery SoH value can be accurately obtained in a plurality of application scenarios, and a battery capacity abnormality risk can be identified in advance, thereby improving stability of an energy storage system.

With reference to the second aspect, in some implementations of the second aspect, the method further includes: sending an alternating current excitation electrical signal to the first cell, where a frequency of the alternating current excitation electrical signal is a preset value; obtaining a sampling signal from the first cell, where the sampling signal includes at least one of voltage information, current information, and temperature information that are of the first cell. The obtaining a real-time equivalent circuit model parameter of the first cell includes: parsing the sampling signal and the alternating current excitation signal to obtain impedance spectrum information of the first cell; and obtaining the real-time equivalent circuit model parameter of the first cell based on the impedance spectrum information of the first cell and a battery equivalent circuit model. The battery equivalent circuit model is preconfigured or stored in a battery monitor unit BMU.

With reference to the second aspect, in some implementations of the second aspect, the method further includes: sending the historical equivalent circuit model parameters of the plurality of cells and the historical actual SoH values of the plurality of cells to the cloud device.

With reference to the second aspect, in some implementations of the second aspect, the method further includes: sending, to the cloud device, the real-time equivalent circuit model parameter of the first cell and an actual SoH value that is of the first cell and that corresponds to the real-time equivalent circuit model parameter of the first cell, where the real-time equivalent circuit model parameter of the first cell and the actual SoH value that is of the first cell and that corresponds to the real-time equivalent circuit model parameter of the first cell are used by the cloud device to update the battery SoH value estimation model, to obtain an updated battery SoH value estimation model.

With reference to the second aspect, in some implementations of the second aspect, the method further includes: receiving the updated battery SoH value estimation model from the cloud device.

According to a third aspect, a battery management system is provided, where the system includes an energy storage apparatus and a cloud device. The energy storage apparatus includes at least one battery pack, where the battery pack includes a plurality of cells, the plurality of cells are connected in series, and the plurality of cells include a first cell. The cloud device is configured to send a battery state of health (SoH) value estimation model to the energy storage apparatus, where the battery SoH value estimation model is obtained by the cloud device through training based on historical equivalent circuit model parameters of the plurality of cells and historical actual SoH values of the plurality of cells, equivalent circuit model parameters of the plurality of cells include at least one of equivalent inductance parameters, equivalent capacitance parameters, and equivalent resistance parameters of the plurality of cells, and the historical equivalent circuit model parameters of the plurality of cells one-to-one correspond to the historical actual SoH values of the plurality of cells. The energy storage apparatus is configured to obtain a real-time equivalent circuit model parameter of the first cell, and obtain an estimated SoH value of the first cell based on the real-time equivalent circuit model parameter of the first cell and the battery SoH value estimation model.

According to the battery management system provided in the embodiments, the energy storage apparatus estimates a battery SoH value by using an artificial intelligence model obtained through training by the cloud device, and deep charging and discharging do not need to be performed on the battery, so that the battery SoH value can be accurately obtained in a plurality of application scenarios, and a battery capacity abnormality risk can be identified in advance, thereby improving stability of an energy storage system.

With reference to the third aspect, in some implementations of the third aspect, the energy storage apparatus is further configured to send the real-time equivalent circuit model parameter of the first cell and an actual SoH value that is of the first cell and that corresponds to the real-time equivalent circuit model parameter of the first cell to the cloud device. The cloud device is further configured to update the battery SoH value estimation model based on the real-time equivalent circuit model parameter of the first cell and the actual SoH value that is of the first cell and that corresponds to the real-time equivalent circuit model parameter of the first cell, to obtain an updated battery SoH value estimation model.

### BRIEF DESCRIPTION OF DRAWINGS

FIG. 1 is a schematic diagram of an application scenario according to the embodiments;

FIG. 2 is a schematic diagram of a structure of an energy storage apparatus according to an embodiment;

FIG. 3 is a schematic diagram of interaction between an energy storage apparatus and a cloud device according to an embodiment;

FIG. 4 is a schematic diagram of a structure in which a battery sampling unit sends an alternating current excitation signal to a first cell according to an embodiment;

FIG. 5 is a schematic diagram of obtaining an equivalent circuit parameter of a cell based on a sampling signal according to an embodiment;

FIG. 6 is a schematic diagram of SoH model training according to an embodiment; and

FIG. 7 shows a correspondence between an equivalent circuit parameter of a cell and an SoH value according to an embodiment.

### DETAILED DESCRIPTION OF EMBODIMENTS

The following describes solutions of the embodiments with reference to accompanying drawings.

Terms used in the following embodiments are merely intended to describe specific embodiments, but are not intended as limiting. The terms “one”, “a” and “this” of singular forms are also intended to include expressions such as “one or more”, unless otherwise specified in the context clearly. It should be further understood that in the following embodiments, “at least one” and “one or more” refer to one, two, or more. The term “and/or” is used for describing an association relationship between associated objects, and indicates that three relationships may exist. For example, A and/or B may represent: only A exists, both A and B exist, and only B exists, where A and B may be singular or plural. The character “/” generally indicates an “or” relationship between the associated objects.

Reference to “one embodiment” or “some embodiments” means that a specific characteristic, structure or feature described in combination with this embodiment is included in one or more embodiments. Therefore, statements such as “in an embodiment”, “in some embodiments”, “in some other embodiments”, and “in other embodiments” that appear at different places do not necessarily mean referring to a same embodiment. Instead, the statements mean “one or more but not all of embodiments”, unless otherwise specifically emphasized in another manner. The terms “include”, “have”, and their variants all mean “include, but are not limited to”, unless otherwise specifically emphasized in another manner.

With the development of energy storage technologies, a lithium-ion battery is increasingly used in various mobile or fixed devices. To ensure stable running of the devices, a power supply battery needs to be managed, to identify potential risks of the battery in advance, and perform maintenance in advance to avoid serious consequences. A battery SoH value is an important parameter in a battery management system. It indicates a ratio of a real-time capacity to a rated capacity of the battery, and is generally expressed in percentage. The battery SoH value can only be obtained by performing a full charge test or a full discharge test on the battery. However, due to a plurality of factors such as safety, the battery cannot be fully charged and discharged. Therefore, the battery SoH value cannot be accurately measured.

Currently, a method widely used in the industry is to establish a relationship between a battery retention capacity and an online detection parameter, and estimate the battery SoH value by using a charge/discharge curve. However, the method needs to first obtain an aging model through a prior aging test that requires a heavy workload and a long period. In addition, in a plurality of power backup scenarios, for example, in scenarios such as a data center and a station backup power supply, the battery is in a float charging state for long time, and a voltage and a current almost remain unchanged. The foregoing method for estimating the battery SoH value based on the charge/discharge curve cannot be performed. Therefore, an energy storage system in the power backup scenario cannot update the SoH value. In this case, the SoH value needs to be updated through periodic inspection to perform deep charging and discharging. This increases operation and management costs.

Based on this, the embodiments provide an energy storage apparatus, a method for obtaining a battery state of health value, and a battery management system, so that a battery SoH value can be accurately obtained in a plurality of application scenarios, such as in an application scenario, for example, a data center, a station backup power supply, an in-vehicle field, or a photovoltaic power supply, in which a battery is in a float charging state or a shallow charging and shallow discharging state for long time, to identify a battery capacity abnormality risk in advance, and improve stability of the energy storage system.

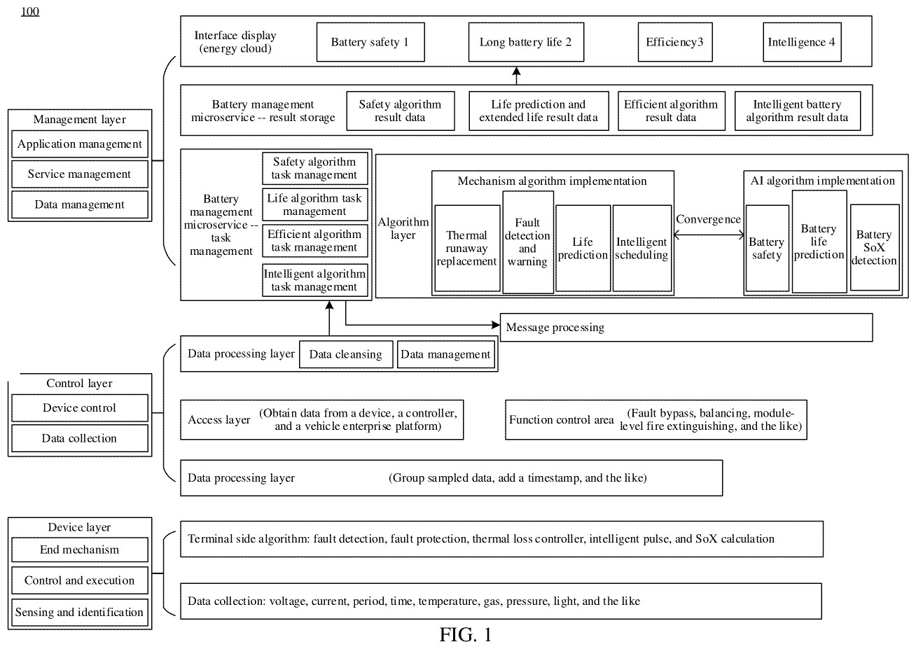

FIG. 1 shows an example application scenario of the embodiments. As shown in FIG. 1, a scenario 100 is a cloud battery management system (BMS), which is also referred to as a cloud BMS. The scenario includes a BMS of a terminal product, a BMS of an energy storage system, and a BMS of an electric vehicle. The BMS is an important link between a battery and the terminal product, the energy storage system, and the electric vehicle. Main functions of the BMS include real-time monitoring of a battery physical parameter, battery state estimation, online diagnosis and warning, energy management, balancing management, and heat management. The cloud BMS that is based on the BMS develops cloud-edge synergy to implement real-time data collection, analysis, state diagnosis, and evaluation of a battery system, and data cleansing and pre-processing. A corresponding algorithm is deployed on the cloud, and a battery running status and a security status are evaluated in a more detailed and comprehensive manner based on more board data. Compared with a traditional board BMS, the cloud BMS has at least the following advantages.
(1) The cloud can store a large amount of data for analysis.
(2) The cloud has more powerful computing capabilities and can deploy more complex algorithms.
(3) The cloud can perform vertical comparison of data and view the time.
(4) The cloud can compare different cells horizontally.
(5) The cloud can incorporate more external information for judgment.

A cloud BMS productization framework may be as follows: at a device layer, a battery terminal (such as an in-vehicle device and an energy storage device) and a control layer upload terminal side data to a cloud platform. The cloud platform parses the data and distributes the data to a mechanism algorithm and an artificial intelligence (AI) algorithm. An algorithm module returns a calculation result to an energy cloud platform, displays the result on a terminal side, and feeds back an analysis conclusion to a battery system maintenance personnel for maintenance and management operations.

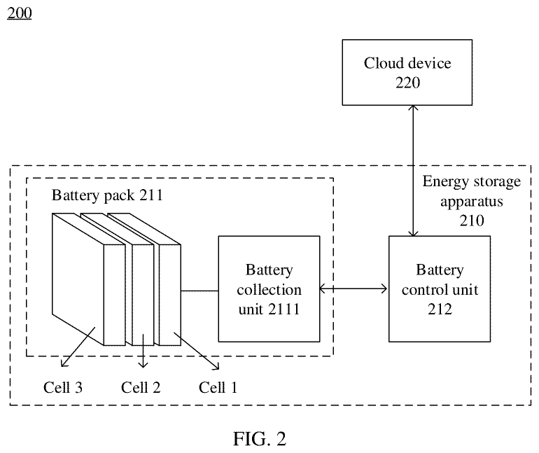

FIG. 2 is a schematic diagram of a structure of an energy storage apparatus according to an embodiment. As shown in FIG. 2, an energy storage apparatus 210 includes a battery control unit BCU 212 and at least one battery pack 211. The battery pack 211 includes a battery monitor unit BMU 2111 and a plurality of cells (for example, a cell 1, a cell 2, and a cell 3), and the plurality of cells are connected in series. The battery control unit BCU 212 is connected to at least one battery pack 211, and the battery monitor unit BMU 2111 is connected to a first cell of the plurality of cells, where the first cell may be one or more of the cell 1, the cell 2, and the cell 3. The battery control unit BCU 212 is configured to receive a battery state of health (SoH) value estimation model from a cloud device 220, where the battery SoH value estimation model is obtained by the cloud device 220 through training based on historical equivalent circuit model parameters of the plurality of cells and historical actual SoH values of the plurality of cells, equivalent circuit model parameters of the plurality of cells include at least one of equivalent inductance parameters, equivalent capacitance parameters, and equivalent resistance parameters of the plurality of cells, and the historical equivalent circuit model parameters of the plurality of cells one-to-one correspond to the historical actual SoH values of the plurality of cells. The battery monitor unit BMU 2111 is configured to obtain a real-time equivalent circuit model parameter of the first cell, and obtain an estimated SoH value of the first cell based on the real-time equivalent circuit model parameter of the first cell and the battery SoH value estimation model.

In this embodiment, the battery monitor unit BMU 2111 is further configured to send an alternating current excitation electrical signal to the first cell, and obtain a sampling signal from the first cell, where the sampling signal is used to obtain the real-time equivalent circuit model parameter of the first cell. The sampling signal includes at least one of voltage information, current information, and temperature information that are of the first cell. A frequency of the alternating current excitation electrical signal is a preset value. For example, a frequency range of the alternating current excitation electrical signal may be any value between 0.001 Hz and 1 MHz or any frequency range. The alternating current excitation electrical signal may be a voltage excitation signal or a current excitation signal. This is not limited.

Optionally, in this embodiment, when sending the alternating current excitation electrical signal to the first cell, the battery monitor unit BMU 2111 may send an alternating current excitation electrical signal of a single frequency at a time, or may superimpose alternating current excitation electrical signals of a plurality of frequencies, and send the alternating current excitation electrical signals to the first cell at the same time. A waveform of the alternating current excitation electrical signal may be any one of a sine wave, a square wave, and a triangular wave, or any combination of a sine wave, a square wave, and a triangular wave.

In this embodiment, a frequency at which the battery monitor unit BMU 2111 obtains the sampling signal from the first cell is f₁, a frequency at which the battery monitor unit BMU 2111 sends the alternating current excitation electrical signal to the first cell is f₂, and f₁ and f₂ meet: f₁≥2f₂. In this way, a sampling frequency is twice or more than a frequency of sending the alternating current excitation electrical signal, so that a change of the sampling signal after the alternating current excitation electrical signal is applied can be accurately learned, and a circuit model parameter of a cell can be parsed from the sampling signal.

Optionally, the battery control unit BCU 212 is further configured to send the historical equivalent circuit model parameters of the plurality of cells and the historical actual SoH values of the plurality of cells to the cloud device 220. The historical equivalent circuit model parameters of the plurality of cells and the historical actual SoH values of the plurality of cells are used by the cloud device to perform model training, to obtain the battery SoH value estimation model.

Optionally, the battery control unit BCU 212 is further configured to send, to the cloud device 220, the real-time equivalent circuit model parameter of the first cell and an actual SoH value that is of the first cell and that corresponds to the real-time equivalent circuit model parameter of the first cell, where the real-time equivalent circuit model parameter of the first cell and the actual SoH value that is of the first cell and that corresponds to the real-time equivalent circuit model parameter of the first cell are used by the cloud device to update the battery SoH value estimation model, to obtain an updated battery SoH value estimation model. In this way, in use of the battery SoH value estimation model, continuous iteration may be performed based on an actual SoH value of a cell and an estimated SoH value of the cell, thereby improving precision of the battery SoH value estimation model.

Optionally, the battery control unit BCU 212 is further configured to receive an updated battery SoH value estimation model from the cloud device 220.

According to the energy storage apparatus in the embodiments, a battery SoH value is estimated by using an artificial intelligence model, and deep charging and discharging do not need to be performed on the battery, so that the battery SoH value can be accurately obtained in a plurality of application scenarios, and a battery capacity abnormality risk can be identified in advance, thereby improving stability of an energy storage system.

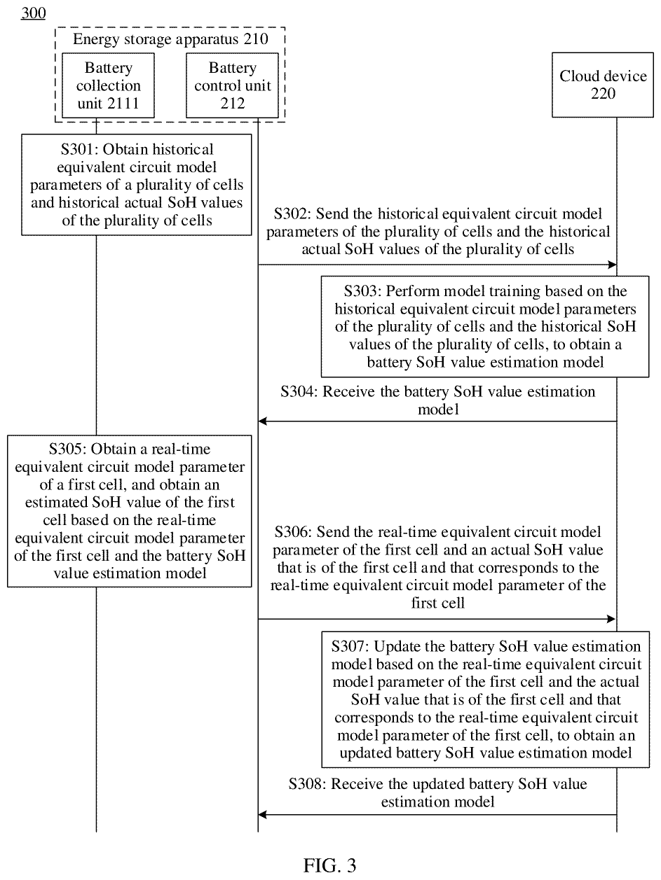

FIG. 3 is a schematic diagram of interaction between an energy storage apparatus 210 and a cloud device 220 according to an embodiment. As shown in FIG. 3, the energy storage apparatus includes a battery monitor unit BMU 2111 and a battery control unit BCU 212. Interaction between the energy storage apparatus 210 and the cloud device 220 may be shown as follows.

S301: The battery monitor unit BMU 2111 obtains historical equivalent circuit model parameters of a plurality of cells and historical actual SoH values of the plurality of cells.

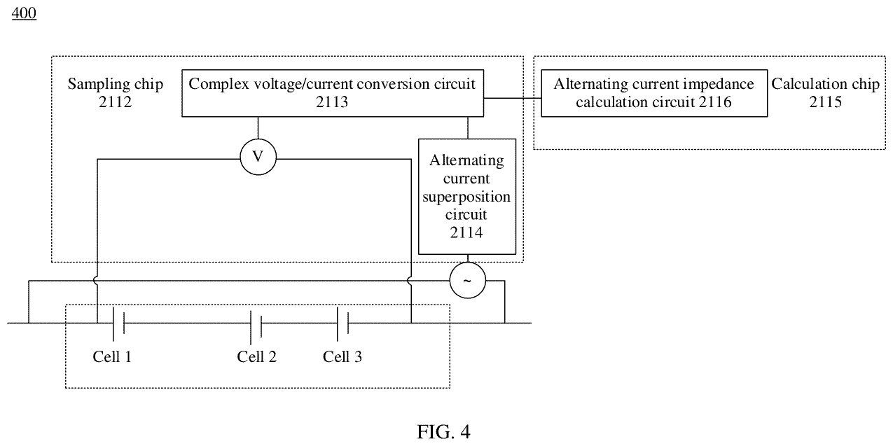

The battery monitor unit BMU 2111 may obtain the historical equivalent circuit model parameters of the cells in a manner of sending an alternating current excitation electrical signal to the plurality of cells, and then obtaining a plurality of sampling signals from the cells. In actual use of these cells, the historical actual SoH values of the cells are obtained based on deep charging and discharging conditions of the cells (or batteries). For example, as shown in FIG. 4, the battery monitor unit BMU 2111 may include a sampling chip 2112 and a calculation chip 2115. The sampling chip 2112 includes a complex voltage/current conversion circuit 2113 and an alternating current superposition circuit 2114. The calculation chip 2115 includes an alternating current impedance calculation circuit 2116. The battery pack 211 includes a cell 1, a cell 2, and a cell 3. The plurality of cells includes the cell 1, the cell 2, and the cell 3 are used an example. The alternating current superposition circuit 2114 is configured to send an alternating current excitation electrical signal to the cell 1, the cell 2, and the cell 3, and the complex voltage/current conversion circuit 2113 is configured to obtain a plurality of sampling signals and the alternating current excitation electrical signal sent by the alternating current superposition circuit 2114. The calculation chip 2115 parses, by using the alternating current impedance calculation circuit 2116, the plurality of sampling signals and the alternating current excitation electrical signal sent by the alternating current superposition circuit 2114, to obtain historical equivalent circuit model parameters of the cell 1, the cell 2, and the cell 3.

For example, when sending the alternating current excitation electrical signals to the cell 1, the cell 2, and the cell 3, the alternating current superposition circuit 2114 may send an alternating current excitation electrical signal of a single frequency at a time, or may superimpose alternating current excitation electrical signals of a plurality of frequencies, and then send the alternating current excitation electrical signals to the cell 1, the cell 2, and the cell 3 at the same time. A frequency of the alternating current excitation electrical signal is a preset value. For example, a frequency range of the alternating current excitation electrical signal may be any value between 0.001 Hz and 1 MHz or any frequency range. The alternating current excitation electrical signal may be a voltage excitation signal or a current excitation signal. This is not limited. A waveform of the alternating current excitation electrical signal may be any one of a sine wave, a square wave, and a triangular wave, or any combination of a sine wave, a square wave, and a triangular wave. The plurality of sampling signals includes at least one of voltage information, current information, and temperature information that are of the cell 1, the cell 2, and the cell 3. The alternating current impedance calculation circuit 2116 is configured to parse the plurality of sampling signals and the alternating current excitation signal to obtain impedance spectrum information of the cell 1, the cell 2, and the cell 3, and obtain the equivalent circuit model parameters of the cell 1, the cell 2, and the cell 3 based on the impedance spectrum information of the cell 1, the cell 2, and the cell 3 and a preconfigured battery equivalent circuit model. The battery equivalent circuit model is preconfigured or stored in the calculation chip 2115, or the battery equivalent circuit model is stored in another unit or module that can be obtained by the calculation chip 2115.

Optionally, a frequency at which the complex voltage/current conversion circuit 2113 obtains the plurality of sampling signals from the cell 1, the cell 2, and the cell 3 is f₁, and a frequency at which the alternating current superposition circuit 2114 sends the alternating current excitation electrical signal to the cell 1, the cell 2, and the cell 3 is f₂, and f₁ and f₂ meet: f₁≥2f₂. In this way, a sampling frequency is twice or more than a frequency of sending the alternating current excitation electrical signal, so that a change of the sampling signal after the alternating current excitation electrical signal is applied can be accurately learned, and a circuit model parameter of a cell can be parsed from the sampling signal.

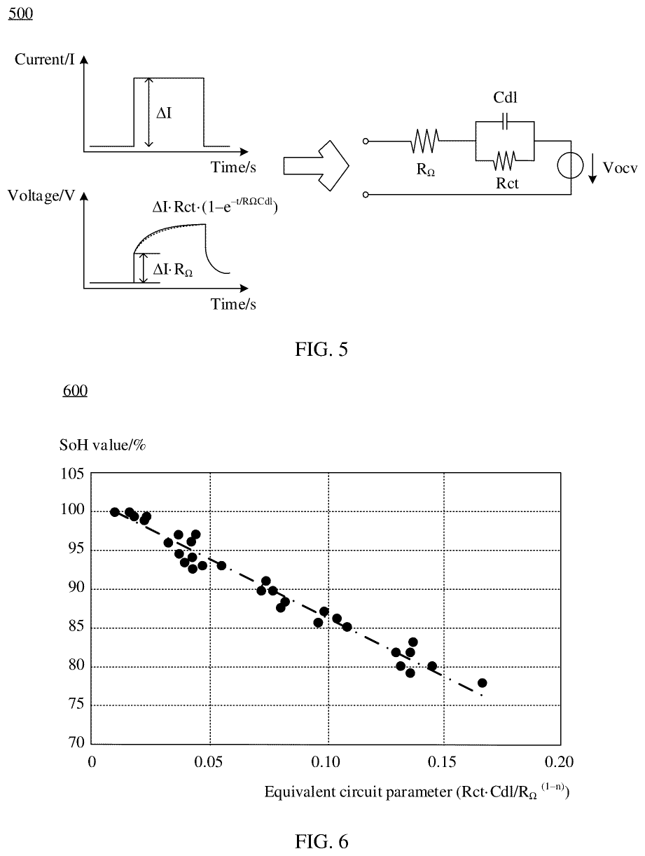

For example, a schematic working diagram of the alternating current impedance calculation circuit 2115 may be shown in FIG. 5. By analyzing a measured voltage signal and a measured circuit signal, various parameters of internal equivalent circuit models of the cell 1, the cell 2, and the cell 3 may be obtained. For example, an equivalent circuit model shown in FIG. 5 is a first-order equivalent circuit model, which may include three parameters: a first resistor R_{Ω}, a second resistor R_{ct}, and a capacitor C_{dl}. A voltage response excitation signal and a current response excitation signal are obtained by applying the alternating current excitation electrical signal to the cell 1, the cell 2, and the cell 3. By analyzing a relationship between the alternating current voltage excitation signal and the response excitation signal, internal equivalent circuit model parameters of the cell 1, the cell 2, and the cell 3 are obtained. For example, R_{Ω} may be obtained through calculation by analyzing instantaneous voltage rise, and the second resistor R_{ct} and the capacitor C_{dl} may be obtained by using a relaxation voltage drop of a period of time after instantaneous voltage drop, and the equivalent circuit model parameters of the cell 1, the cell 2, and the cell 3 are obtained.

As shown in FIG. 6, when a cell ages, an internal material and a structure of the cell change, and these changes are reflected in an equivalent circuit model parameter of the cell. Therefore, by analyzing the change of the equivalent circuit model parameter, an aging degree of the cell can be represented, that is, battery SoH estimation can be implemented.

S302: The battery control unit BCU 212 sends the historical equivalent circuit model parameters of the plurality of cells and the historical actual SoH values of the plurality of cells to the cloud device 220.

Correspondingly, the cloud device 220 receives the historical equivalent circuit model parameters of the plurality of cells and the historical actual SoH values of the plurality of cells from the battery control unit BCU 212.

In actual use of a battery, a cause of capacity attenuation of the battery can be a result of coupling of a plurality of factors. Calculation workload to obtain a relationship between an estimated battery SoH value and variables based on corresponding manually-fitting parameters is heavy, and it is difficult to have a correct expression. Therefore, in this embodiment, the battery control unit BCU 212 in the energy storage apparatus 210 may upload, to the cloud device 220, the cell equivalent circuit model parameter obtained by the battery monitor unit BMU 2111 based on the sampling signal and the alternating current excitation electrical signal. The cloud device 220 establishes a relationship between the battery equivalent circuit model parameter and the battery SoH value by using an AI big data analysis method.

S303: The cloud device 220 performs model training based on the historical equivalent circuit model parameters of the plurality of cells and the historical SoH values of the plurality of cells, to obtain the battery SoH value estimation model.

For example, the cloud device performs big data online training based on the historical equivalent circuit model parameters of the plurality of cells and the historical SoH values of the plurality of cells, and outputs a correlation relationship between the equivalent circuit model parameters of the cells and the SoH values of the cells, that is, the battery SoH value estimation model, by using comparison of historical features of a single cell and horizontal comparison of a plurality of cells.

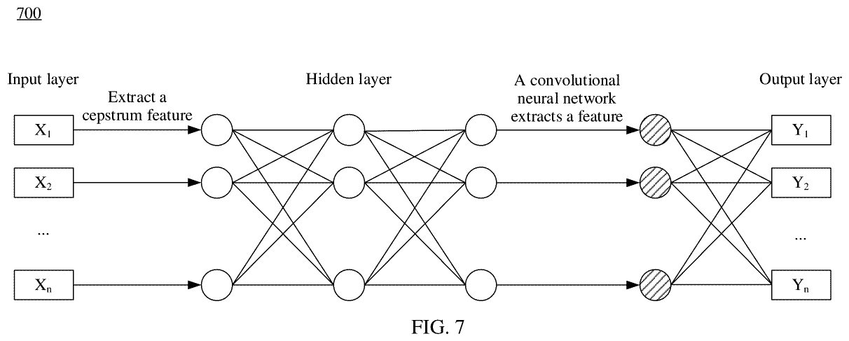

For example, a process in which the cloud device 220 performs model training to obtain the battery SoH value estimation model may be shown in FIG. 7. Input parameters X₁ and X₂ of an input layer may be historical equivalent circuit model parameters of the cell 1, the cell 2, and the cell 3. After a cepstrum feature is extracted from the input parameter, the cepstrum feature is input to a hidden layer for big data online training. Training is performed by using comparison of historical features of a single cell and horizontal comparison of a plurality of cells. A feature is extracted by using a convolutional neural network. Output parameters Y₁, Y₂, and the like of an output layer may be estimated SoH values of the cell 1, the cell 2, and the cell 3. The battery SoH value estimation model obtained through model training of the cloud device 220 can output an estimated SoH value of a cell based on an equivalent circuit model parameter of any cell.

S304: The battery control unit BCU 212 receives a battery SoH value estimation model from the cloud device 220.

Correspondingly, the cloud device 220 sends the battery SoH value estimation model to the battery control unit BCU 212.

S305: The battery monitor unit BMU 2111 obtains a real-time equivalent circuit model parameter of the first cell, and obtains an estimated SoH value of the first cell based on the real-time equivalent circuit model parameter of the first cell and the battery SoH value estimation model.

The first cell may be one or more of the cell 1, the cell 2, and the cell 3. For a process that the battery monitor unit BMU 2111 obtains the real-time equivalent circuit model parameter of the first cell, refer to the process shown in FIG. 4. Details are not described herein again. It should be noted that, the battery monitor unit BMU 2111 obtains the real-time equivalent circuit model parameter of the first cell by using the sampling signal. In this way, accuracy of data can be ensured, thereby improving accuracy of the obtained estimated SoH value.

Optionally, after obtaining the estimated SoH value corresponding to the real-time equivalent circuit model parameter of the first cell, the battery monitor unit BMU 2111 may display the estimated SoH value on a battery terminal, so that an operation and maintenance personnel observes, maintains, and manages the battery.

S306: The battery control unit BCU 212 is further configured to send, to the cloud device 220, the real-time equivalent circuit model parameter of the first cell and an actual SoH value corresponding to the real-time equivalent circuit model parameter of the first cell.

Correspondingly, the cloud device 220 receives, from the battery control unit BCU 212, the real-time equivalent circuit model parameter of the first cell and the actual SoH value corresponding to the real-time equivalent circuit model parameter of the first cell.

The actual SoH value corresponding to the real-time equivalent circuit model parameter of the first cell refers to an SoH value obtained by performing deep charging and discharging of the first cell in actual use, and is different from an estimated SoH value obtained by using the battery SoH value estimation model.

S307: The cloud device 220 updates the battery SoH value estimation model based on the real-time equivalent circuit model parameter of the first cell and the actual SoH value corresponding to the real-time equivalent circuit model parameter of the first cell, to obtain an updated battery SoH value estimation model.

For example, the cloud device 220 continuously performs continuous iteration based on the estimated SoH value obtained by the battery monitor unit BMU 2111 in a process of using the model and the actual SoH value obtained by deep charging and discharging in a process of using the cell, to update the battery SoH value estimation model, to improve precision of the battery SoH value estimation model. For a continuous iteration process, refer to the conventional technology. Details are not described herein again.

S308: The battery control unit BCU receives the updated battery SoH value estimation model from the cloud device 220.

Correspondingly, the cloud device 220 sends the updated battery SoH value estimation model to the battery control unit BCU 212.

According to the energy storage apparatus in the embodiments, a battery SoH value is estimated by using an artificial intelligence model, and deep charging and discharging do not need to be performed on the battery, so that the battery SoH value can be accurately obtained in a plurality of application scenarios, and a battery capacity abnormality risk can be identified in advance, thereby improving stability of an energy storage system. In addition, the energy storage apparatus and the cloud device in the embodiments can further obtain continuous iteration of an actual battery SoH value with reference to a deep charge/discharge usage state in actual use, thereby improving model precision.

An embodiment further provides a battery management system. The battery management system includes the energy storage apparatus and the cloud device described above. The energy storage apparatus includes at least one battery pack, where the battery pack includes a plurality of cells, the plurality of cells is connected in series, and the plurality of cells include a first cell. Optionally, the battery management system may further include another device that communicates with the energy storage device or the cloud device.

In embodiments, it should be understood that the system, apparatus, and method may be implemented in other manners. The described apparatus embodiment is merely an example. For example, division into the units is merely logical function division and may be other division in actual implementation. For example, a plurality of units or components may be combined or integrated into another system, or some features may be ignored or not performed. In addition, the displayed or discussed mutual couplings or direct couplings or communication connections may be implemented by using some interfaces. The indirect couplings or communication connections between the apparatuses or units may be implemented in electronic, mechanical, or other forms.

The units described as separate parts may or may not be physically separate, and parts displayed as units may or may not be physical units, may be located in one position, or may be distributed on a plurality of network units. Some or all of the units may be selected based on actual requirements to achieve the objectives of the solutions of embodiments.

In addition, functional units in embodiments may be integrated into one processing unit, each of the units may exist alone physically, or two or more units are integrated into one unit.

When the functions are implemented in the form of a software functional unit and sold or used as an independent product, the functions may be stored in a non-transitory computer-readable storage medium. Based on such an understanding, the solutions of the embodiments essentially, or the part contributing to the prior art, or some of the solutions may be implemented in a form of a software product. The software product is stored in a non-transitory storage medium, and includes several instructions for instructing a computer device (which may be a personal computer, a server, or a network device) to perform all or some of the steps of the methods described in the embodiments. The foregoing non-transitory storage medium includes any medium that can store program code, such as a USB flash drive, a removable hard disk, a read-only memory (ROM), a random access memory (RAM), a magnetic disk, or an optical disc.

The foregoing descriptions are merely implementations of the embodiments, but are not intended as limiting. Any variation or replacement readily figured out by a person skilled in the art shall fall within the scope of this embodiments.

1. An energy storage apparatus, comprising:
a battery control unit (BCU) and at least one battery pack, the battery pack comprises a battery monitor unit (BMU) and a plurality of cells, the plurality of cells is connected in series, the battery control unit (BCU) is connected to the at least one battery pack, and the battery monitor unit (BMU) is connected to a first cell of the plurality of cells;
the battery control unit (BCU) is configured to receive a battery state of health (SoH) value estimation model from a cloud device, wherein the battery SoH value estimation model is obtained by the cloud device through training based on historical equivalent circuit model parameters of the plurality of cells and historical actual SoH values of the plurality of cells, equivalent circuit model parameters of the plurality of cells comprise at least one of equivalent inductance parameters, equivalent capacitance parameters, and equivalent resistance parameters of the plurality of cells, and the historical equivalent circuit model parameters of the plurality of cells one-to-one correspond to the historical actual SoH values of the plurality of cells; and
the battery monitor unit (BMU) is configured to obtain a real-time equivalent circuit model parameter of the first cell, and obtain an estimated SoH value of the first cell based on the real-time equivalent circuit model parameter of the first cell and the battery SoH value estimation model.

2. The energy storage apparatus according to claim 1, wherein the battery monitor unit (BMU) is further configured to:
send an alternating current excitation electrical signal to the first cell, wherein a frequency of the alternating current excitation electrical signal is a preset value; and
obtain a sampling signal from the first cell, wherein the sampling signal is used to obtain the real-time equivalent circuit model parameter of the first cell, and the sampling signal comprises at least one of voltage information, current information, and temperature information that are of the first cell.

3. The energy storage apparatus according to claim 2, wherein a frequency at which the battery monitor unit (BMU) obtains the sampling signal from the first cell is f₁, a frequency at which the battery monitor unit (BMU) sends the alternating current excitation electrical signal to the first cell is f₂, and f₁ and f₂ meet:
f₁≥2f₂.

4. The energy storage apparatus according to claim 1, wherein the battery monitor unit (BMU) is further configured to:
parse the sampling signal and the alternating current excitation signal to obtain impedance spectrum information of the first cell; and
obtain the real-time equivalent circuit model parameter of the first cell based on the impedance spectrum information of the first cell and a battery equivalent circuit model, wherein
the battery equivalent circuit model is preconfigured or stored in the battery monitor unit (BMU).

5. The energy storage apparatus according to claim 1, wherein the battery control unit (BCU) is further configured to:
send the historical equivalent circuit model parameters of the plurality of cells and the historical actual SoH values of the plurality of cells to the cloud device.

6. The energy storage apparatus according to claim 1, wherein the battery control unit (BCU) is further configured to:
send, to the cloud device, the real-time equivalent circuit model parameter of the first cell and an actual SoH value that is of the first cell and that corresponds to the real-time equivalent circuit model parameter of the first cell, wherein the real-time equivalent circuit model parameter of the first cell and the actual SoH value that is of the first cell and that corresponds to the real-time equivalent circuit model parameter of the first cell are used by the cloud device to update the battery SoH value estimation model, to obtain an updated battery SoH value estimation model.

7. The energy storage apparatus according to claim 1, wherein the battery control unit (BCU) is further configured to:
receive the updated battery SoH value estimation model from the cloud device.

8. The energy storage apparatus according to claim 2, wherein a waveform of the alternating current excitation electrical signal comprises at least one of a sine wave, a square wave, or a triangular wave.

9. A method for obtaining a battery state of health (SoH) value, wherein the method is executed by an energy storage apparatus, the energy storage apparatus comprises at least one battery pack, the battery pack comprises a plurality of cells, the plurality of cells is connected in series, and the plurality of cells comprise a first cell;
the method comprising:
receiving a battery SoH value estimation model from a cloud device, wherein the battery SoH value estimation model is obtained by the cloud device through training based on historical equivalent circuit model parameters of the plurality of cells and historical actual SoH values of the plurality of cells, equivalent circuit model parameters of the plurality of cells comprise at least one of equivalent inductance parameters, equivalent capacitance parameters, and equivalent resistance parameters of the plurality of cells, and the historical equivalent circuit model parameters of the plurality of cells one-to-one correspond to the historical actual SoH values of the plurality of cells; and
obtaining a real-time equivalent circuit model parameter of the first cell, and obtaining an estimated SoH value of the first cell based on the real-time equivalent circuit model parameter of the first cell and the battery SoH value estimation model.

10. The method according to claim 9, further comprising:
sending an alternating current excitation electrical signal to the first cell, wherein a frequency of the alternating current excitation electrical signal is a preset value;
obtaining a sampling signal from the first cell, wherein the sampling signal comprises at least one of voltage information, current information, and temperature information that are of the first cell; and
the obtaining a real-time equivalent circuit model parameter of the first cell comprises:
parsing the sampling signal and the alternating current excitation signal to obtain impedance spectrum information of the first cell; and
obtaining the real-time equivalent circuit model parameter of the first cell based on the impedance spectrum information of the first cell and a battery equivalent circuit model, wherein
the battery equivalent circuit model is preconfigured or stored in the battery monitor unit (BMU).

11. The method according to claim 9, further comprising:
sending the historical equivalent circuit model parameters of the plurality of cells and the historical actual SoH values of the plurality of cells to the cloud device.

12. The method according to claim 9, further comprising:
sending, to the cloud device, the real-time equivalent circuit model parameter of the first cell and an actual SoH value that is of the first cell and that corresponds to the real-time equivalent circuit model parameter of the first cell, wherein the real-time equivalent circuit model parameter of the first cell and the actual SoH value that is of the first cell and that corresponds to the real-time equivalent circuit model parameter of the first cell are used by the cloud device to update the battery SoH value estimation model, to obtain an updated battery SoH value estimation model.

13. The method according to claim 9, further comprising:
receiving the updated battery SoH value estimation model from the cloud device.

14. A battery management system, comprising:
an energy storage apparatus, the energy storage apparatus comprises at least one battery pack, the battery pack comprises a plurality of cells, the plurality of cells is connected in series, and the plurality of cells comprise a first cell;
and
a cloud device,
the cloud device is configured to send a battery state of health (SoH) value estimation model to the energy storage apparatus, wherein the battery SoH value estimation model is obtained by the cloud device through training based on historical equivalent circuit model parameters of the plurality of cells and historical actual SoH values of the plurality of cells, equivalent circuit model parameters of the plurality of cells comprise at least one of equivalent inductance parameters, equivalent capacitance parameters, and equivalent resistance parameters of the plurality of cells, and the historical equivalent circuit model parameters of the plurality of cells one-to-one correspond to the historical actual SoH values of the plurality of cells; and
the energy storage apparatus is configured to obtain a real-time equivalent circuit model parameter of the first cell; and obtain an estimated SoH value of the first cell based on the real-time equivalent circuit model parameter of the first cell and the battery SoH value estimation model.

15. The system according to claim 14, wherein the energy storage apparatus is further configured to send the real-time equivalent circuit model parameter of the first cell and an actual SoH value that is of the first cell and that corresponds to the real-time equivalent circuit model parameter of the first cell to the cloud device; and
the cloud device is further configured to update the battery SoH value estimation model based on the real-time equivalent circuit model parameter of the first cell and the actual SoH value that is of the first cell and that corresponds to the real-time equivalent circuit model parameter of the first cell, to obtain an updated battery SoH value estimation model.
